(19) United States
(12) Patent Application Publication
(10) Pub. No.: US 2024/0075740 A1
(43) Pub. Date: Mar. 7, 2024

(54) INKJET HEAD UNIT AND SUBSTRATE TREATMENT APPARATUS INCLUDING THE SAME

(71) Applicant: SEMES CO., LTD., Chungcheongnam-do (KR)

(72) Inventors: Jang Mi WOO, Chungcheongnam-do (KR); Jin Hyuck Yang, Chungcheongnam-do (KR); Yong Kyu Cho, Chungcheongnam-do (KR); Cheon Su Cho, Chungcheongnam-do (KR); Ki Hoon Choi, Chungcheongnam-do (KR)

(21) Appl. No.: 18/225,668

(22) Filed: Jul. 24, 2023

(30) Foreign Application Priority Data
Sep. 6, 2022 (KR) 10-2022-0112661

(51) Int. Cl. B41J 2/14; B41J 2/045

(52) U.S. Cl. CPC B41J 2/1433; B41J 2/04563; B41J 2/04581; B41J 2/16579

(57) ABSTRACT

An inkjet head unit capable of performing high-resolution pixel printing on a large-size substrate and a substrate treatment apparatus including the inkjet head unit are provided. The substrate treatment apparatus includes: a processing unit supporting and moving a substrate; an inkjet head unit performing pixel printing on the substrate; and a gantry unit moving the inkjet head unit over the substrate, wherein the inkjet head unit includes head packs, which include a plurality of nozzles ejecting a substrate treatment liquid onto the substrate, and a head base, in which the head packs are installed and the head packs are disposed in a single row in the head base.

### CROSS-REFERENCE TO RELATED APPLICATION

This application claims priority from Korean Patent Application No. 10-2022-0112661 filed on Sep. 6, 2022 in the Korean Intellectual Property Office, and all the benefits accruing therefrom under 35 U.S.C. 119, the contents of which in its entirety are herein incorporated by reference.

### BACKGROUND

### 1. Field

The present disclosure relates to an inkjet head unit and a substrate treatment apparatus including the same, and more particularly, to an inkjet head unit for use in the manufacture of a semiconductor device or a display device and a substrate treatment apparatus including the inkjet head unit.

### 2. Description of the Related Art

A display manufacturing process includes a plurality of treatment steps for forming elements for emitting light on a substrate (e.g., a transparent glass substrate). For example, the treatment processes may include coating, exposure, deposition, cleaning, and etching. The treatment processes may be sequentially performed by manufacturing equipment in a display manufacturing plant. As one of the treatment processes, an inkjet printing process for forming a film or pattern by discharging ink droplets on a substrate has been introduced.

The inkjet printing process is performed by ejecting ink on a substrate. To eject ink on the substrate, inkjet printing equipment is disposed in a display manufacturing plant, and the inkjet printing process may be performed by the inkjet printing equipment.

Meanwhile, as the demand for large-size devices has increased, the production of large-size substrates has increased, and accordingly, a method of efficiently perform inkjet printing on a large-size substrate is required.

### SUMMARY

Aspects of the present disclosure provide an inkjet head unit capable of efficiently perform pixel printing on a large-size substrate and a substrate treatment apparatus including the inkjet head unit.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a substrate treatment apparatus includes: a processing unit supporting and moving a substrate; an inkjet head unit performing pixel printing on the substrate; and a gantry unit moving the inkjet head unit over the substrate, wherein the inkjet head unit includes head packs, which include a plurality of nozzles ejecting a substrate treatment liquid onto the substrate, and a head base, in which the head packs are installed and the head packs are disposed in a single row in the head base.

According to another aspect of the present disclosure, a substrate treatment apparatus includes: a processing unit supporting and moving a substrate; an inkjet head unit performing pixel printing on the substrate; a gantry unit moving the inkjet head unit over the substrate; and a maintenance unit for the maintenance of the inkjet head unit, wherein the inkjet head unit includes head packs, which include a plurality of nozzles ejecting a substrate treatment liquid onto the substrate, a head base, in which the head packs are installed, and a head frame, which is installed on the head base and includes a storage tank storing the substrate treatment liquid and a pressure control module controlling a meniscus associated with the substrate treatment liquid, at the nozzles, the head packs are disposed in a single row in the head base, the head packs include first and second head packs, which are adjacent to each other and are of different types, a nozzle of the first head pack that is adjacent to the second head pack does not overlap with a nozzle of the second head pack that is adjacent to the first head pack, a size of the head packs combined is the same as a size of the substrate, and a first stage of the processing unit and a second stage of the maintenance unit are disposed side-by-side in a moving direction of the gantry unit.

According to another aspect of the present disclosure, an inkjet head unit performing pixel printing on a substrate includes: head packs including a plurality of nozzles, which eject a substrate treatment liquid onto the substrate; a head base in which the head packs are installed; and a head frame installed on the head base, the head frame including a storage tank, which stores the substrate treatment liquid, and a pressure control module, which controls a meniscus associated with the substrate treatment liquid, at the nozzles, wherein the head packs are disposed in a single row in the head base.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a plan view of a substrate treatment apparatus according to an embodiment of the present disclosure, which is provided as inkjet printing equipment;

FIG. 2 illustrates an exemplary layout of a plurality of head packs in a head base of the substrate treatment apparatus of FIG. 1;

FIG. 3 illustrates the internal structure of an inkjet head unit of the substrate treatment apparatus of FIG. 1;

FIG. 4 illustrates problems associated with an inkjet head unit with the head packs of FIG. 2;

FIG. 5 illustrates another exemplary layout of the head packs in the head base;

FIG. 6 illustrates the benefits of an inkjet head unit with the head packs of FIG. 5;

FIG. 7 illustrates another exemplary layout of the head packs in the head base;

FIG. 8 illustrates how to treat a substrate with the head packs of FIG. 7;

FIG. 9 illustrates another exemplary layout of the head packs in the head base;

FIG. 10 illustrates an exemplary substrate printing method of the inkjet head unit;

FIG. 11 illustrates another exemplary substrate printing method of the inkjet head unit;

FIG. 12 illustrates an exemplary layout of a printing zone and a maintenance zone;

FIG. 13 illustrates another exemplary layout of the printing zone and the maintenance zone;

FIG. 14 illustrates an exemplary gantry unit for supporting the inkjet head unit;

FIG. 15 illustrates another exemplary gantry unit for supporting the inkjet head unit;

FIG. 16 illustrates a temperature control unit of the substrate treatment apparatus of FIG. 1;

FIG. 17 illustrates a temperature measurement unit of the substrate treatment apparatus of FIG. 1; and

FIG. 18 illustrates an inspection unit of the substrate treatment apparatus of FIG. 1.

### DETAILED DESCRIPTION

Embodiments of the present disclosure will be described with reference to the attached drawings. Like reference numerals indicate like elements throughout the present disclosure, and thus, detailed descriptions thereof will be omitted.

The present disclosure relates to inkjet printing equipment capable of perform high-resolution pixel printing on a large-size substrate and an operating method of the inkjet printing equipment.

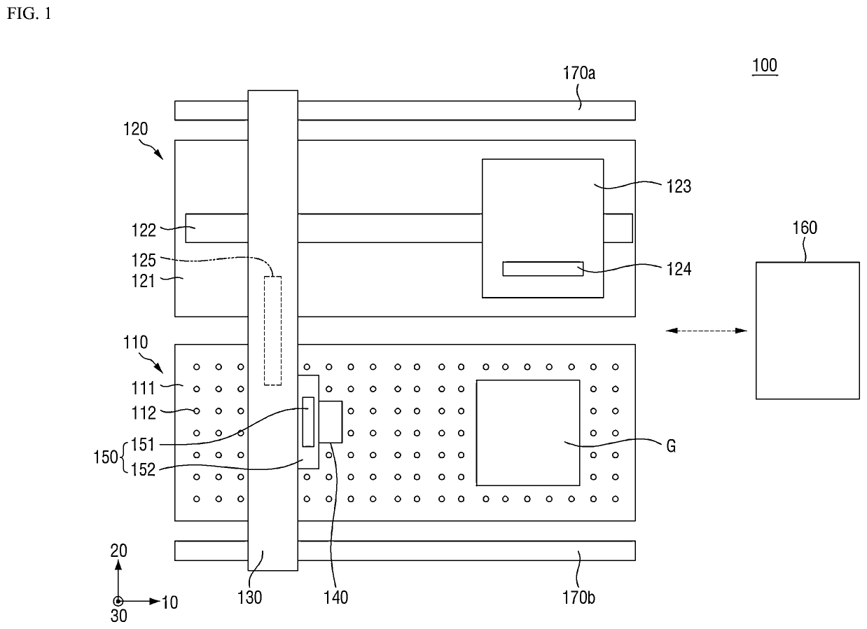

FIG. 1 is a plan view of a substrate treatment apparatus according to an embodiment of the present disclosure, which is provided as inkjet printing equipment.

Referring to FIG. 1, a substrate treatment apparatus 100 may include a processing unit 110, a maintenance unit 120, a gantry unit 130, an inkjet head unit 140, a substrate treatment liquid providing unit 150, and a control unit 160.

The substrate treatment apparatus 100 may treat a substrate G (e.g., a transparent glass substrate), which is used to fabricate a display device. The substrate treatment apparatus 100 may be provided as inkjet printing equipment for performing a printing process by ejecting a substrate treatment liquid onto the substrate G via the inkjet head unit 140.

The substrate treatment apparatus 100 may use ink as the substrate treatment liquid. Here, the substrate treatment liquid refers to a chemical liquid used to perform printing on the substrate G. The substrate treatment apparatus 100 may be provided as inkjet printing equipment for forming color filters on the substrate G with ink. The substrate treatment apparatus 100 may perform pixel printing on the substrate G using the substrate treatment liquid and may be provided as circulating inkjet printing equipment to prevent nozzles from being clogged by the substrate treatment liquid.

The processing unit 110 supports the substrate G while performing printing on the substrate G with the substrate treatment liquid. The processing unit 110 may support the substrate G in a non-contact manner. The processing unit 110 may support the substrate G by lifting the substrate G up in the air, but the present disclosure is not limited thereto. The processing unit 110 may support the substrate Gin a contact manner. The processing unit 110 may support the substrate G with a support member (e.g., a chuck) having a seating surface provided thereon.

The processing unit 110 may move the substrate G while supporting the substrate G with air. For example, the processing unit 110 may include a first stage 111 and air holes 112.

The first stage 111, which is a base, may be provided to have the substrate G mounted thereon. The air holes 112 may be formed to penetrate the top of the first stage 111. A plurality of air holes 112 may be formed in a printing zone on the first stage 111.

The air holes 112 may spray air in an upward direction with respect to the first stage 111, i.e., in a third direction 30. The air holes 112 may lift the substrate G, which is mounted on the first stage 111, up in the air.

Although not specifically illustrated in FIG. 1, the processing unit 110 may further include a gripper and a guide rail. The gripper holds the substrate G and prevents the substrate G from being separated from the first stage 111 when the substrate G is moving in the length direction of the first stage 111, i.e., in a first direction 10. The gripper may move in the same direction as the substrate W along the guide rail, while gripping the substrate G. The gripper and the guide rail may be provided on the outside of the first stage 111.

The maintenance unit 120 measures ejection positions (i.e., target points) on the substrate G where the substrate treatment liquid is to be ejected and whether the substrate treatment liquid has been ejected. The maintenance unit 120 may measure the target points for a plurality of nozzles of the inkjet head unit 140 and whether the substrate treatment liquid has been ejected by each of the nozzles and may provide the results of the measurement to the control unit 160.

The maintenance unit 120 may include a calibration board, on which a plurality of alignment marks for measuring the ejection positions for the substrate treatment liquid are displayed, and a camera module, which is for capturing an image of the alignment marks. For example, the maintenance unit 120 may include a second stage 121, a third guide rail 122, a first plate 123, a calibration board 124, and a camera module 125.

The second stage 121, which is a base like the first stage 111, may be disposed in parallel to the first stage 111. The second stage 121 may have a maintenance zone thereon. The second stage 121 may have the same size as the first stage 111. Alternatively, the second stage 121 may a smaller or larger size than the first stage 111.

The third guide rail 122 guides the moving path of the first plate 123. The third guide rail 122 may be provided on the second stage 121 as at least one line along the length direction of the second stage 121, i.e., along the first direction 10. The third guide rail 122 may be implemented as, for example, a linear motor guide system.

Although not specifically illustrated in FIG. 1, the maintenance unit 120 may further include a fourth guide rail. The fourth guide rail, like the third guide rail 122, guides the moving path of the first path 123. The fourth guide rail may be provided on the second stage 121 as at least one line along the width direction of the second stage 121, i.e., along the second direction 20.

The first plate 123 may move over the second stage 121 along the third guide rail 122 and/or the fourth guide rail. The first plate 123 may move along the third guide rail 122, side-by-side with the substrate G, and may move close to, or away from, the substrate G along the fourth guide rail.

The calibration board 124 is for measuring the ejection positions on the substrate G for the substrate treatment liquid. The calibration board 124 may include alignment marks or a graduated ruler and may be installed on the first plate 123 along the length direction of the first plate 123, i.e., along the first direction 10.

Although not specifically illustrated in FIG. 1, the calibration board 124 may be provided near the inkjet head unit 140, together with measurement equipment (e.g., the camera module 125) for determining the state of the substrate treatment liquid being ejected. For example, the calibration board 124 and the measurement equipment may be installed in the gantry unit 130.

The camera module 125 may acquire image information regarding the substrate G. The image information regarding the substrate G may include whether and where the substrate treatment liquid has been ejected and the amount by which, and the size of the area over which the substrate treatment liquid has been ejected. The camera module 125 may acquire not only the image information regarding the substrate G, but also information regarding the calibration board 124.

In the case of treating the substrate G, the camera module 125 may acquire the image information regarding the substrate in real time. The camera module 125 may acquire the image information regarding the substrate G by capturing an image of the substrate Gin a length direction (i.e., in the first direction 10), in which case, the camera module 125 may include a line scan camera. Alternatively, the camera module 125 may acquire the image information regarding the substrate G by capturing images of areas of the substrate G that have a particular size, in which case, the camera module 125 may include an area scan camera.

The camera module 125 may be attached on the bottom surface or a side of the gantry unit 130 to acquire the image information regarding the substrate G, but the present disclosure is not limited thereto. Alternatively, the camera module 125 may be attached on a side of the inkjet head unit 140. At least one camera module 125 may be provided in the substrate treatment apparatus 100 and may be installed to be fixed or movable.

The gantry unit 130 supports the inkjet head unit 140. The gantry unit 130 may be provided above the first and second stages 111 and 121 such that the inkjet head unit 140 may eject the substrate treatment liquid onto the substrate G.

The gantry unit 130 may be provided on the first and second stages 111 and 121 to extend along the width direction of the first and second stages 111 and 121 (i.e., along the second direction). The gantry unit 130 may move in the length direction of the first and second stages 111 and 121 (i.e., in the first direction 10) along first and second guide rails 170a and 170b. The first and second guide rails 170a and 170b may be provided on the outside of the first and second stages 111 and 121, along the length direction of the first and second stages 111 and 121 (i.e., along the first direction 10).

As already mentioned above, the gantry unit 130 may include, for example, a graduated ruler for determining the exact location of the inkjet head unit 140 and may also include measurement equipment for correcting the accuracy of position data.

Although not specifically illustrated, the substrate treatment apparatus 100 may further include a gantry moving unit. The gantry moving unit may slidably move the gantry unit 130 along the first and second guide rails 170a and 170b. The gantry moving unit may be installed in the gantry unit 130.

The inkjet head unit 140 ejects the substrate treatment liquid onto the substrate Gin the form of droplets. The inkjet head unit 140 may be installed on a side or the bottom surface of the gantry unit 130.

At least one inkjet head unit 140 may be installed in the gantry unit 130. In a case where a plurality of inkjet head units 140 are installed in the gantry unit 130, the plurality of inkjet head units 140 may be arranged in a row along the length direction of the gantry unit 130 (i.e., along the second direction 20). Also, the plurality of inkjet head units 140 may operate independently or collectively.

The inkjet head unit 140 may be movable along the length direction of the gantry unit 130 (i.e., along the second direction 20) to be placed at a desired location on the substrate G, but the present disclosure is not limited thereto. The inkjet head unit 140 may be movable along the height direction of the gantry unit 130 (i.e., along the third direction 30) and may be rotatable clockwise or counterclockwise.

The inkjet head unit 140 may be fixedly installed in the gantry unit 130. In this case, the gantry unit 130 may be provided to be movable.

Although not specifically illustrated, the substrate treatment apparatus 100 may further include an inkjet head moving unit. The inkjet head moving unit may rectilinearly move or rotate the inkjet head unit 140.

The substrate treatment liquid providing unit 150 is a reservoir providing the substrate treatment liquid to the inkjet head unit 140. The substrate treatment liquid providing unit 150 may be installed in the gantry unit 130 and may include a storage tank 151 and a pressure control module 152.

The storage tank 151 stores the substrate treatment liquid, and the pressure control module 152 controls the pressure in the storage tank 151. The storage tank 151 may supply an appropriate amount of substrate treatment liquid to the inkjet head unit 140 based on the pressure provided by the pressure control module 152.

The inkjet head unit 140 and the substrate treatment liquid providing unit 150 may be incorporated into a single integral module. For example, the inkjet head unit 140 and the substrate treatment liquid providing unit 150 may be disposed at the front of the gantry unit 130, and the substrate treatment liquid providing unit 150 may be disposed above the inkjet head unit 140. However, the present disclosure is not limited to this example. The substrate treatment liquid providing unit 150 may be configured as a separate module from the inkjet head unit 140. For example, the inkjet head unit 140 and the substrate treatment liquid providing unit 150 may be separately provided at the front and rear of the gantry unit 130.

The control unit 160 controls the operations of the elements of the substrate treatment apparatus 100. The control unit 160 may control, for example, the air holes 112 and the gripper of the processing unit 110, the camera module 125 of the maintenance unit 120, the gantry unit 130, the inkjet head unit 140, and the pressure control module 152 of the substrate treatment liquid providing unit 150.

The control unit 160 may be implemented as a computer or a server including a process controller, a control program, an input module, an output module (or a display module), and a memory module. Here, the process controller may include a microprocessor controlling each of the elements of the substrate treatment apparatus 100, the control program may execute various treatments to be performed by the substrate treatment apparatus 100 under the control of the process controller, and the memory module stores programs for executing the various treatments to be performed by the substrate treatment apparatus 100, i.e., treatment recipes, in accordance with various data and treatment conditions.

The control unit 160 may perform maintenance for the inkjet head unit 140. For example, the control unit 160 may correct the ejection positions for the nozzles of the inkjet head unit 140 based on the result of measurement performed by the maintenance unit 120, may detect any defective nozzles that have failed to eject the substrate treatment liquid from among the nozzles of the inkjet head unit 140, and may perform a cleaning process on the defective nozzles.

The substrate treatment apparatus 100 may be a piezoelectric inkjet printing system. In this case, the substrate treatment apparatus 100 may drop the substrate treatment liquid as droplets through the nozzles of the inkjet head unit 140 in accordance with the voltage applied to each of piezoelectric elements thereof.

In a case where the substrate treatment apparatus 100 is provided as a piezoelectric inkjet printing system, the inkjet head unit 140 may include piezoelectric elements, a nozzle plate, and a plurality of nozzles. The nozzle plate may form the body of the inkjet head unit 140. The nozzles may be provided in multiple rows and multiple columns, a predetermined distance apart from the bottom of the nozzle plate, and as many piezoelectric elements as there are nozzles in the nozzle plate may be provided. In this case, the inkjet head unit 140 may eject the substrate treatment liquid onto the substrate G through the nozzles in accordance with the operation of the piezoelectric elements.

The inkjet head unit 140 may control the amount of substrate treatment liquid provided via each of the nozzles independently in accordance with the voltage applied to each of the piezoelectric elements.

As already mentioned above, the present disclosure relates to a substrate treatment apparatus 100 capable of performing high-resolution pixel printing on a large-size substrate. The substrate treatment apparatus 100 may include a processing unit 110, which includes a first stage 111 (e.g., an air floating stage) with air holes 112 for supporting and moving the substrate G, an inkjet head unit 140, which ejects a substrate treatment liquid (e.g., ink) onto the substrate G, a gantry unit 130, which supports and moves the inkjet head unit 140, and a maintenance unit 120, which inspects and cares the inkjet head unit 140.

The size of the substrate treatment apparatus 100 can be considerably reduced as compared to an existing substrate treatment apparatus, and can perform high-resolution pixel printing on a large-size substrate, within a relatively short amount of time. This will hereinafter be described in further detail.

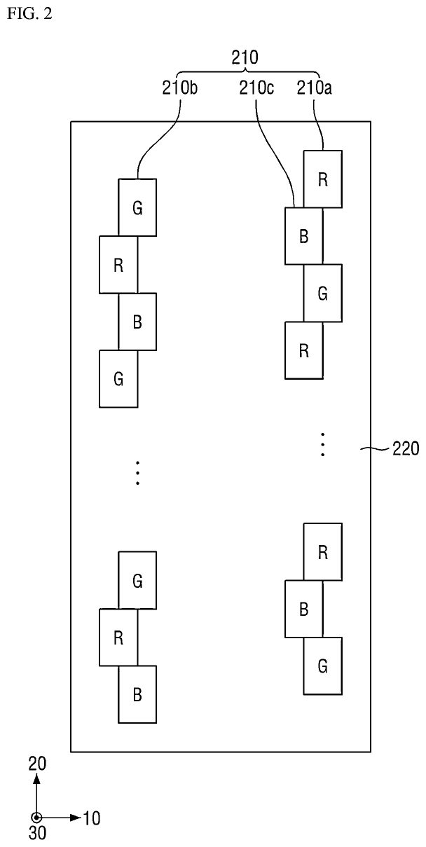

First, the inkjet head unit 140 will hereinafter be described. FIG. 2 illustrates an exemplary layout of a plurality of head packs 210 in a head base 220.

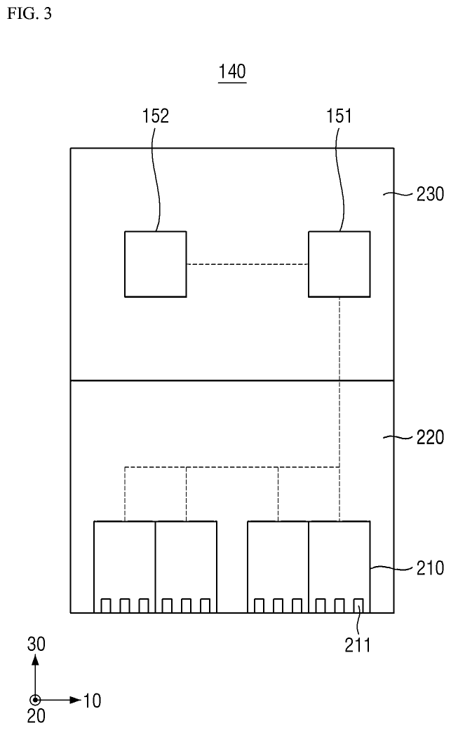

Referring to FIG. 3, the inkjet head unit 140 may include head packs 210, a head base 220, and a head frame 230. FIG. 3 illustrates the inner structure of the inkjet head unit 140 of the substrate treatment apparatus 100.

Referring to FIGS. 2 and 3, the head packs 210 include groups of nozzles for performing pixel printing on the substrate G. The head packs 210 may be formed to have the same size. Each of the head packs 210 may eject a substrate treatment liquid of a particular color onto the substrate G. For example, first head packs 210a (“R”) may eject red ink onto the substrate G, second head packs 210b (“G”) may eject green ink onto the substrate G, and third head packs 210c (B″) may eject blue ink onto the substrate G.

Each of the head packs 210 may include a plurality of heads. For example, each of the head packs 210 may include four heads, and each of the heads may include a plurality of nozzles. The number of heads in each of the heads packs 210 may be increased to improve the resolution of an image formed on the substrate G. In another example, each of the head packs 210 may include five heads.

Alternatively, heads may be arranged in each of the head packs 210 not in a single column, but in at least two columns, to improve the resolution of an image formed on the substrate G.

The head base 220 may be installed to include a plurality of head packs 210. The head packs 210 may expose multiple nozzles 211 at the bottom surface of the head base 220 such that the substrate treatment liquid may be able to be ejected. The head packs 210 may be arranged in the head base 220 in multiple columns, in a zigzag fashion across the multiple columns.

For example, referring to FIG. 2, the head packs 210 may be arranged in the order of “R,” “G,” and “B” in a zigzag fashion across two columns. In this example, a first head pack 210a ejecting red ink onto the substrate G may be arranged at the front of the array of the head packs 210, a second head pack 210b ejecting green ink onto the substrate G may be arranged behind the first head pack 210a, and a third head pack 210c ejecting blue ink onto the substrate G may be arranged behind the second head pack 210b.

The distance between the first and second head packs 210a and 210b may be optimized by arranging the first and second head packs 210a and 210b such that the last nozzle of the first head pack 210a may overlap with the first nozzle of the second head pack 210b. The second and third head packs 210a and 210b and the third head pack 210c and another first head pack 210a may be arranged in the same manner as the first and second head packs 210a and 210b.

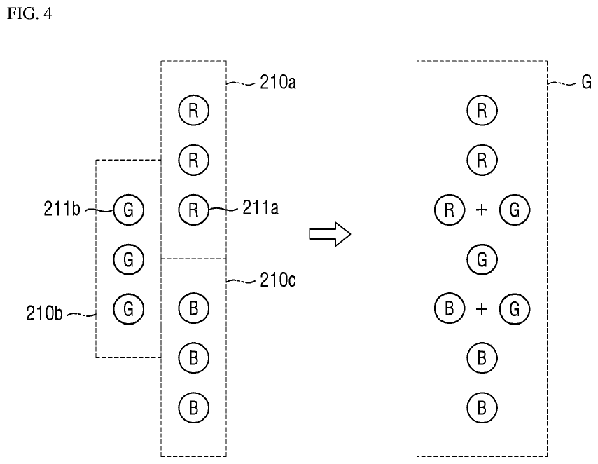

Specifically, referring to FIG. 4, when the head packs 210 are arranged in the head base 220, as illustrated in FIG. 2, no empty space is formed between a last nozzle 211a of a first head pack 210a and a first nozzle 211b of a second head pack 210b. In this case, a problem arises in which red ink and green ink ejected from the last nozzle 211a of the first head pack 210a and the first nozzle 211b of the second head pack 210b, respectively, may overlap with each other on the substrate G. FIG. 4 illustrates the problems associated with an inkjet head unit with the head packs of FIG. 2.

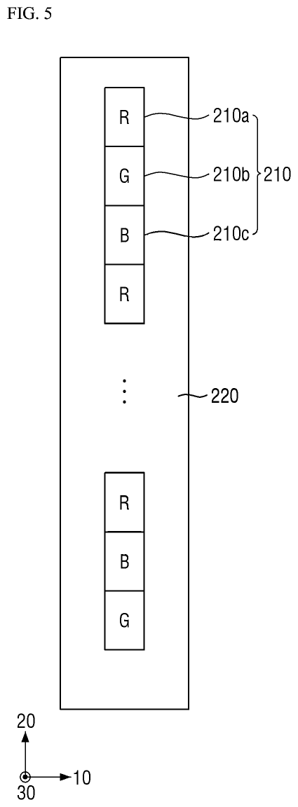

Referring to FIG. 5, in some embodiments of the present disclosure, the head packs 210 may be arranged in the head base 220 in a single column in the order of “R,” “G,” and “B,” as illustrated in FIG. 5. FIG. 5 illustrates another exemplary layout of the head packs 210 in the head base 220.

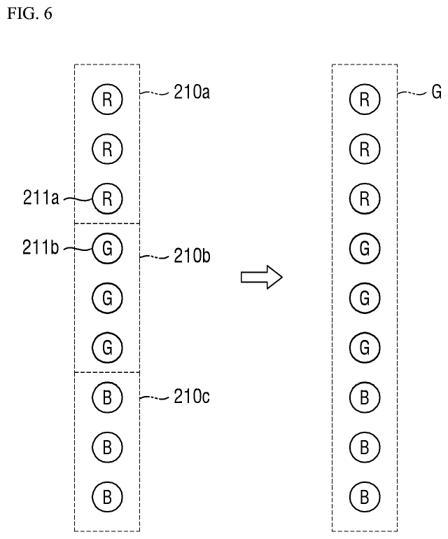

Specifically, referring to FIG. 6, when the head packs 210 are arranged in the head base 220, as illustrated in FIG. 5, an empty space is formed between a last nozzle 211a of a first head pack 210a and a first nozzle 211b of a second head pack 210b, and red ink and green ink ejected from the last nozzle 211a of the first head pack 210a and the first nozzle 211b of the second head pack 210b, respectively, may not overlap with each other on the substrate G. FIG. 6 illustrates the benefits of an inkjet head unit 140 with the head packs 210 of FIG. 5.

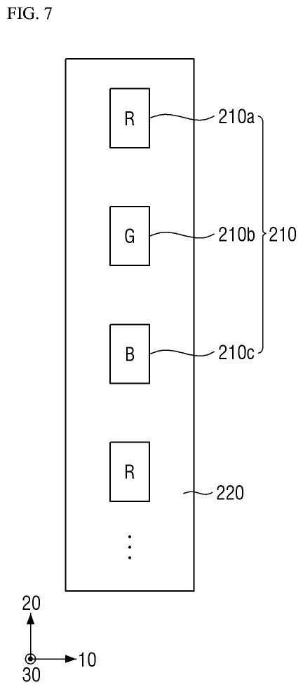

Referring to FIG. 7, in some embodiments of the present disclosure, the head packs 2100 may be arranged in a single column to be a predetermined distance apart from one another, rather than being arranged in a single column to be in contact with one another, as illustrated in FIG. 5. For example, a first head pack 210a and a second head pack 210b may be spaced apart from each other, and the second head pack 210b and a third head pack 210c may be spaced apart from each other.

Here, the distance between the first and second head packs 210a and 210b may be the same as the distance between the size of the first head pack 210a. Alternatively, the distance between the first and second head packs 210a and 210b may be the same as the size of the second head pack 210b. The first and second head packs 210a and 210b may have the same size.

Similarly, the distance between the second and third head packs 210b and 210c may be the same as the size of the second head pack 210b. Alternatively, the distance between the second and third head packs 210b and 210c may be the same as the size of the third head pack 210c. The second and third head packs 210b and 210c may have the same size. FIG. 7 illustrates another exemplary layout of the head packs 210 in the head base 220.

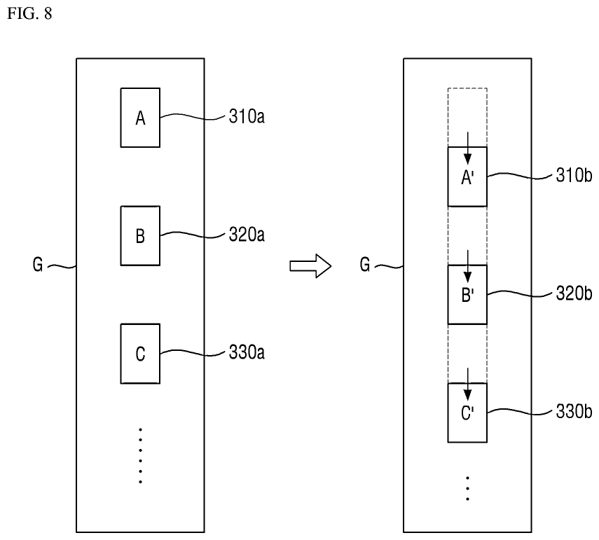

Referring to FIGS. 7 and 8, if the first, second, and third head packs 210a, 210b, and 210c have the same size, the distance between the first and second head packs 210a and 210b is the same as the size of one of the first and second head packs 210a and 210b, and the distance between the second and third head packs 210b and 210c is the same as the size of one of the second and third head packs 210b and 210c, the first, second, and third head packs 210a, 210b, and 210c may eject a substrate treatment liquid at points A (“310a”), B (“320a”), and C (“330a”), respectively, move to points A′ (“310b”), B′ (“320b”), and C′ (“330b”), respectively, and eject the substrate treatment liquid at points A′, B′, and C′, respectively. In this case, the substrate treatment liquid can be uniformly ejected over the entire surface of the substrate G. FIG. 8 illustrates how to treat the substrate G with the head packs 210 of FIG. 7.

Referring again to FIG. 3, the head frame 230 fixes the head base 220. The substrate treatment liquid providing unit 150, i.e., the storage tank 151 and the pressure control module 152, may be installed in the head frame 230. The storage tank 151 may supply the substrate treatment liquid to each of the head packs 210 or the nozzles 211 in each of the head packs 210, and the pressure control module 152 may control the meniscus of each of the nozzles 211.

The head frame 230 may be disposed on the head base 220. The storage tank 151 and the pressure control module 152 may be disposed above the head packs 210.

The storage tank 151 and the pressure control module 152 may be disposed side-by-side in a front-to-rear direction (i.e., in the first direction 10) or in a left-to-right direction (i.e., in the second direction 20). For example, the storage tank 151 may be disposed at the front, and the pressure control module 152 may be disposed at the rear. However, the present disclosure is not limited to this example. Alternatively, the storage tank 151 and the pressure control module 152 may be arranged in a top-to-bottom direction (i.e., in the third direction 30). For example, the pressure control module 152 may be disposed above the storage tank 151.

Alternatively, in order to reduce the weight of the inkjet head unit 140 and minimize the fluctuation of the storage tank 151 that may be caused by the head packs 210, the storage tank 151 and the pressure control module 152 may be installed in the gantry unit 130 to be separate from the inkjet head unit 140 or may be installed on the outside of the substrate treatment apparatus 100. For example, in a case where the substrate treatment liquid providing unit 150 is installed to be separate from the inkjet head unit 140, the inkjet head unit 140 and the substrate treatment liquid providing unit 150 may be disposed on both sides of the gantry unit 130.

In a case where the head packs 210 are arranged in the head base 220, as illustrated in FIG. 2, the layout of the nozzles 211 of the inkjet head unit 140 may be designed such that the nozzles 211 may be able to properly cover the pixel area of the substrate G. When the substrate G enters and exits the substrate treatment apparatus 100 through the front and the rear, respectively, of the substrate treatment apparatus 100 and then moves from the rear to the front of the substrate treatment apparatus 100, the inkjet head unit 140 may perform its operation, moving in a direction orthogonal to the substrate G. However, when the head packs 210 are arranged in the head base 220, as illustrated in FIG. 2, a printing zone needs to be divided into smaller sub-printing zones that can be handled by the inkjet head unit 140, and a printing process needs to be performed in units of the sub-printing zones. For example, if the printing zone is divided into two sub-printing zones, the printing process needs to be performed twice.

On the contrary, in a case where the head packs 210 are arranged in the head base 220, as illustrated in FIG. 5, the nozzles 211 may be arranged in a single column without overlapping with one another, as illustrated in FIG. 6. When the substrate G enters and exits the substrate treatment apparatus 100 through the front and the rear, respectively, of the substrate treatment apparatus 100 and then moves from the rear to the front of the substrate treatment apparatus 100, the inkjet head unit 140 may perform its operation, moving in the direction orthogonal to the substrate G. When the head packs 210 are arranged in the head base 220, as illustrated in FIG. 5, the printing zone of the substrate G does not need to be divided into smaller sub-printing zones, regardless of whether the substrate G is a large-size substrate, and the substrate G can be pixel-printed at once.

The head packs 210 may be arranged in the order of “R,” “G,” and “B” and may be designed such that the distance between the head packs 210 and a column of the nozzles 211 may become uniform. The head packs 210 may be arranged in the order of “R,” “G,” and “B” along the width direction of the substrate G and may move in the width direction of the substrate G by the same amount such that red, green, and blue may all be printed on the substrate G.

The head packs 210 include groups of nozzles 211 and use the nozzles 211 depending on the resolution of an image to be formed on the substrate G via printing. When using multiple nozzles 211, the nozzles 211 may be arranged to overlap to meet a particular resolution. The number of head packs 210 installed in the inkjet head unit 140 may be determined by the size of the substrate G.

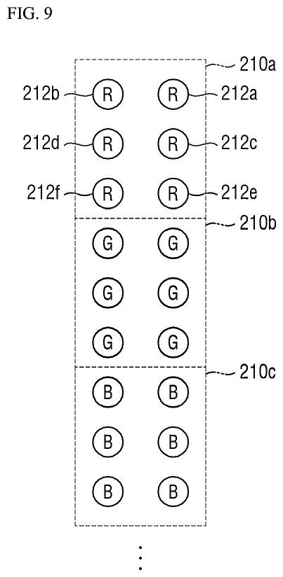

The nozzles 211 in each of the head packs 210 may be configured to overlap depending on the particular resolution. For example, referring to FIG. 9, first and second nozzles 212a and 212b may be disposed in a first head pack 210 to overlap with each other, third and fourth nozzles 212c and 212d may be disposed in the first head pack 210 to overlap with each other, and fifth and sixth nozzles 212e and 212f may be disposed in the first head pack 210 to overlap with each other.

FIG. 9 illustrates that the first and second nozzles 212a and 212b completely overlap with each other, but the present disclosure is not limited thereto. Alternatively, the first and second nozzles 212a and 212b may only partially overlap with each other. The third and fourth nozzles 212c and 212d may be arranged in the same manner as the first and second nozzles 212a and 212b, and the fifth and sixth nozzles 212e and 212f may also be arranged in the same manner as the first and second nozzles 212a and 212b.

If the first and second nozzles 212a and 212b are disposed to partially overlap with each other, the second nozzle 212b may overlap not only with the first nozzle 212a, but also with the third nozzle 212c. FIG. 9 illustrates another exemplary layout of the head packs 210 in the head base 220.

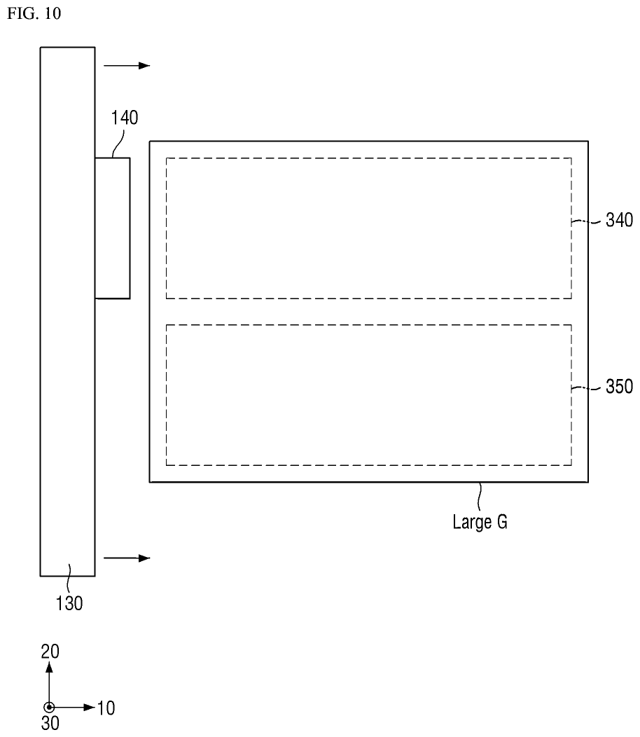

As already mentioned above, when the head packs 210 are arranged in the head base 220, as illustrated in FIG. 2, the inkjet head unit 140 cannot cover the entire substrate G at once. Thus, referring to FIG. 10, the substrate G may be divided into multiple printing zones, for example, first and second printing zones 340 and 350, and a printing process may be performed on each of the first and second printing zones 340 and 350. FIG. 10 illustrates an exemplary substrate printing method of the inkjet head unit 140.

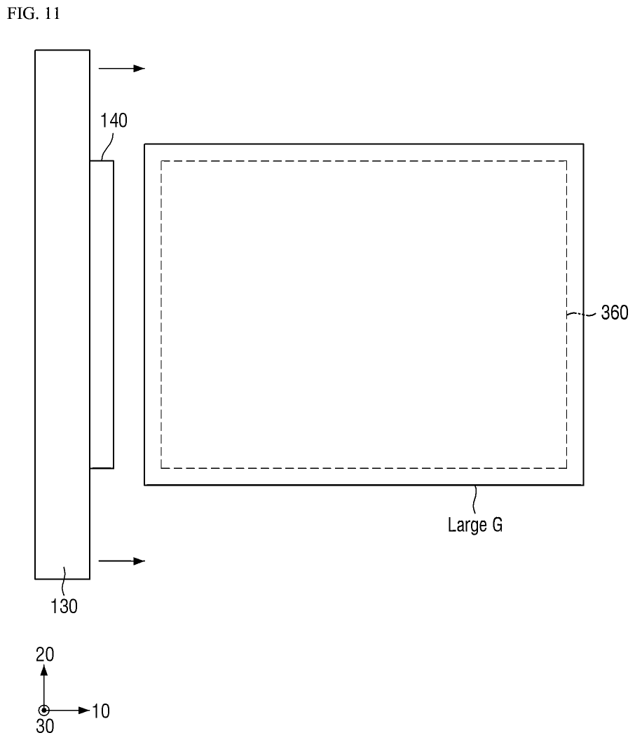

On the contrary, when the head packs 210 are arranged in the head base 220, as illustrated in FIG. 5, the inkjet head unit 140 can cover the entire substrate G at once. Thus, referring to FIG. 11, a printing process may be performed on a printing zone 360 of the substrate G without dividing the printing zone 360 into smaller sub-printing zones. FIG. 11 illustrates another exemplary substrate printing method of the inkjet head unit 140.

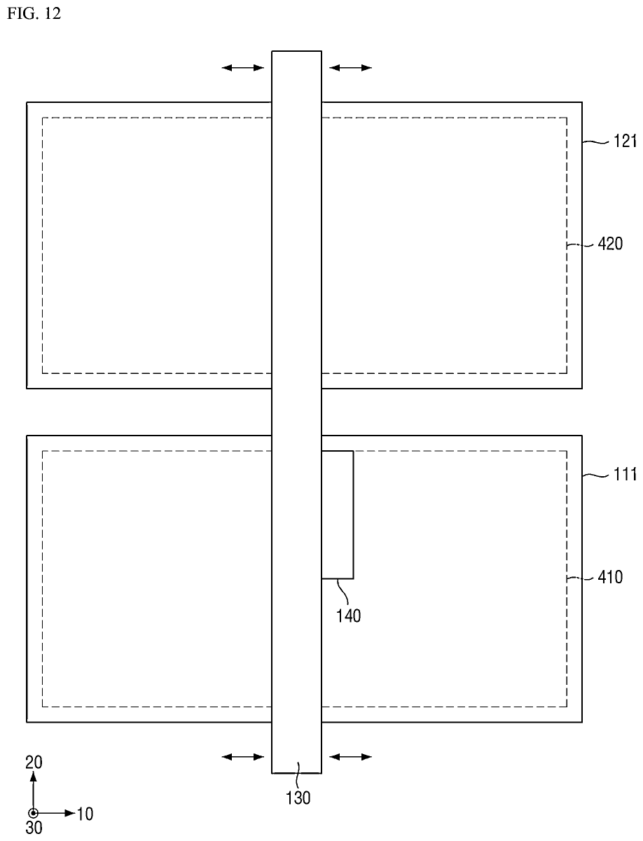

When maintenance is needed, the inkjet head unit 140 may move from a printing zone 410 of the first stage 111 to a maintenance zone 420 of the second stage 121. Various inspections such as, for example, nozzle inspection and droplet inspection, may be conducted in the maintenance zone 420. FIG. 12 illustrates an exemplary layout of the printing zone 410 and the maintenance zone 420.

Referring to FIG. 12, the printing zone 410 and the maintenance zone 420 may be disposed in a direction orthogonal to the moving direction of the inkjet head unit 140 or to the moving direction of the gantry unit 130 when treating the substrate G. For example, if the inkjet head unit 140 treats the substrate G, moving reciprocally in the first direction 10, the printing zone 410 and the maintenance zone 420 may be disposed side-by-side in the second direction 20, which is orthogonal to the first direction 10. In this example, nozzle correction deviation may arise due to the separation of the printing zone 410 and the maintenance zone 420.

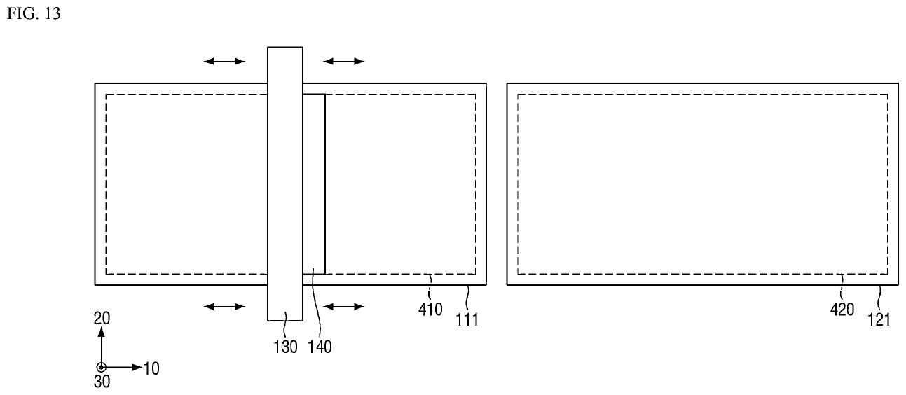

Alternatively, referring to FIG. 13, the printing zone 410 and the maintenance zone 420 may be disposed in a direction parallel to the moving direction of the inkjet head unit 140 or to the moving direction of the gantry unit 130 when treating the substrate G. For example, if the inkjet head unit 140 treats the substrate G, moving reciprocally in the first direction 10, the printing zone 410 and the maintenance zone 420 may be disposed side-by-side in the first direction 10. In this example, ejection measurement error that may be caused by the non-separation of the printing zone 410 and the maintenance zone 420 can be minimized. FIG. 13 illustrates another exemplary layout of the printing zone 410 and the maintenance zone 420.

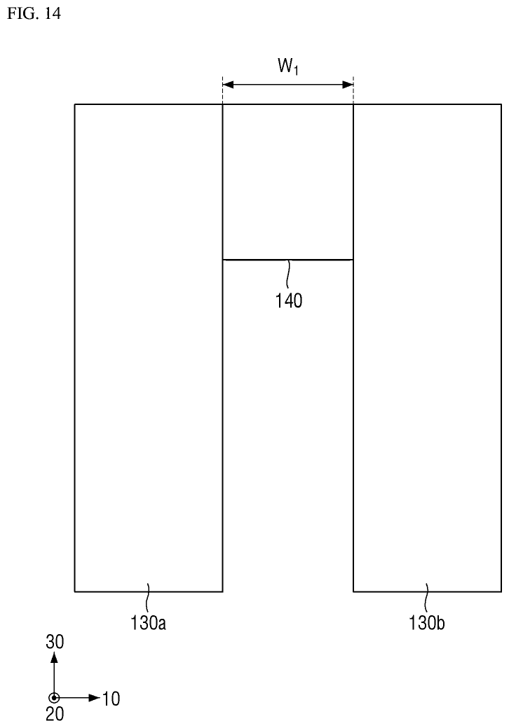

When the head packs 210 are arranged in the head base 220, as illustrated in FIG. 2, it may be difficult to support the inkjet head unit 140 with a single gantry unit 130 due to a large width W₁ of the inkjet head unit 140, the accuracy of the ejection of ink may be lowered due to vibration generated during the movement of the inkjet head unit 140, and the substrate treatment may roll considerably. To address these problems, referring to FIG. 14, a dual gantry unit (130a and 130b) may be provided to support the inkjet head unit 140 on both sides of the inkjet head unit 140. FIG. 14 illustrates an exemplary gantry unit (130a and 130b) for supporting the inkjet head unit 140.

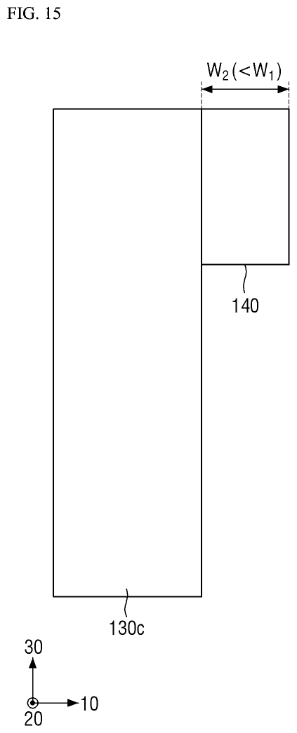

On the contrary, referring to FIG. 15, when the head packs are arranged in the head base 220, as illustrated in FIG. 5, the inkjet head unit 140 may be able to be easily supported with a single gantry unit 130c because of a narrow width W₂ of the inkjet head unit 140, which is smaller than W₁, and the problems associated with the inkjet head unit 140 of FIG. 14 may not arise. FIG. 15 illustrates another exemplary gantry unit 130c for supporting the inkjet head unit 140.

Measurement equipment for identifying a printed state of the substrate G may be installed at the front of the inkjet head unit 140. Alternatively, the measurement equipment may be positioned at the rear of the inkjet head unit 140 with the gantry unit 130 interposed therebetween.

The measurement equipment may be equipment for measuring the alignment of the substrate G before printing, the ejection of the substrate treatment liquid onto the substrate G during printing, the alignment of the nozzles 211, the target points for the substrate treatment liquid, the speed and volume of droplets, and the accuracy of the target points for the substrate treatment liquid. The measurement equipment may be optical equipment such as, for example, the camera module 125.

As already mentioned above, the substrate G may be placed on a chuck, and during printing, the substrate G may be printed on by moving the chuck. Alternatively, the substrate G may be printed on by moving the substrate G in an air floating method using the first stage 111 with the air holes 112 formed thereon.

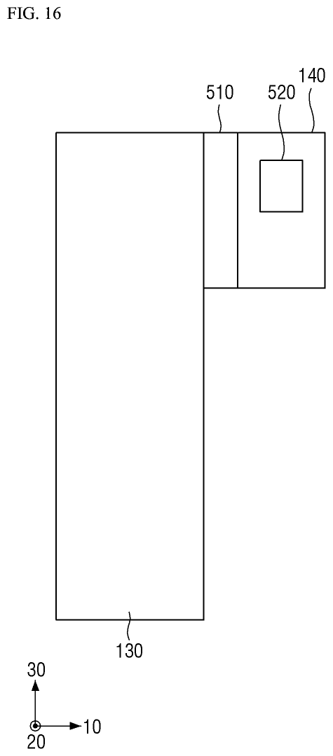

Referring to FIG. 16, the substrate treatment apparatus 100 may further include a temperature control unit 510 to address the thermal deformation of the equipment and control the viscosity of the substrate treatment liquid. The temperature control unit 510, which is for controlling the temperature of the substrate treatment liquid, may be disposed between the gantry unit 130 and the inkjet head unit 140. Temperature changes may affect the nozzles 211 of the inkjet head unit 140. To address this, the temperature control unit 510 may be disposed between the gantry unit 130 and the inkjet head unit 140. FIG. 16 illustrates the temperature control unit 510 of the substrate treatment apparatus 100.

The temperature control unit 510 may be installed close to the inside or the outside of the inkjet head unit 140. For example, the temperature control unit 510 may be installed in the head base 220 or in the head frame 230. In another example, the temperature control unit 510 may be attached to an outer surface of the head base 220 or an outer surface of the head frame 230.

Alternatively, the temperature control unit 510 may be installed close to the inside or the outside of the first stage 111. For example, the temperature control unit 510 may be installed in the first stage 111 or on an outer surface of the first stage 111. In another example, the temperature control unit 510 may be installed in the gantry unit 130.

When the inkjet head unit 140 starts ejecting ink, a heater 520 in the inkjet head unit 140 may operate. In this case, the temperature control unit 510 and the heater 520 may operate at the same time, or the temperature control unit 510 may operate after the heater 520. The heater 510, which is installed in the inkjet head unit 140, may be automatically turned off when the temperature reaches a reference level, and may be turned back on and operate when the temperature becomes lower than the reference level. The heater 520 may be feedback-controlled.

The temperature control unit 510 may control not only the temperature of the substrate treatment liquid, but also the temperature of the substrate G, which is a target object to be treated. The temperature control unit 510 may be installed on the inside or the outside of the first stage 111. For example, the temperature control unit 510 may be provided in the first stage 111 as a cooling passage or as a device sending cool air toward the substrate G. In a case where the temperature control unit 510 supports and moves the substrate G in the air floating method, the temperature control unit 510 may send cool air to the outside. The temperature control unit 510 may operate under the control of the control unit 160.

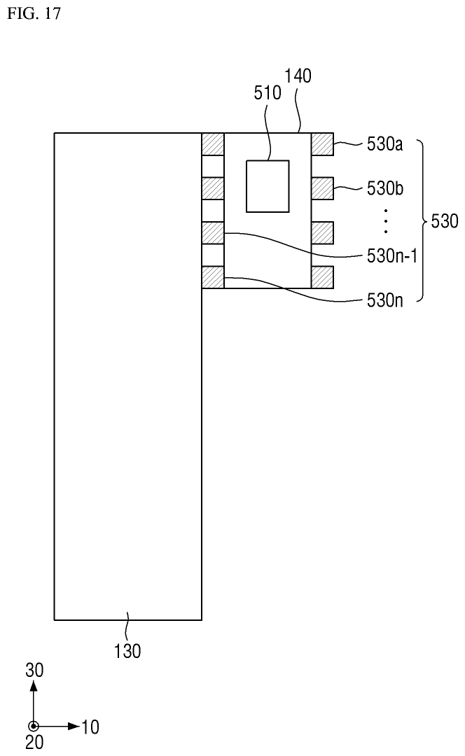

Referring to FIG. 17, the substrate treatment apparatus 100 may further include temperature measurement units 530. A plurality of temperature measurement units 530a, 530b, . . . , 530n-1, and 530n may be installed along the outer circumference of the inkjet head unit 140. For example, the temperature measurement units 530a, 530b, . . . , 530n-1, and 530n may be installed at the front of the inkjet head unit 140, between the gantry unit 130 and the inkjet head unit 140. In this example, the temperature control unit 510 may operate using the temperature measurement units 530a, 530b, . . . , 530n-1, and 530n, which are installed at the front of the inkjet head unit 140, and the differences in temperature between the temperature measurement units 530a, 530b, . . . , 530n-1, and 530n. FIG. 17 illustrates the temperature measurement units 530 of the substrate treatment apparatus 100.

The first stage 111, which moves the substrate G during the treatment of the substrate G, may be positioned between the gantry unit 130 and the inkjet head unit 140 and may use the air floating method. In a case where high-resolution printing is performed on the substrate G, which is a large-size substrate, the substrate G needs to be maintained flat during operation, and stains and particles should not be generated. Thus, the substrate G may be provided as an air floating stage.

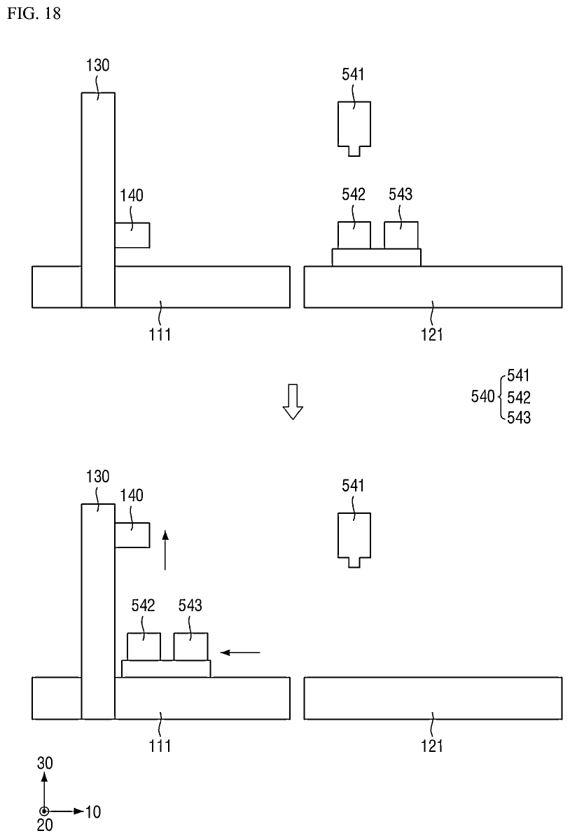

An inspection unit 540 of the maintenance unit 120 may perform various inspections and cleaning for the inkjet head unit 140. Referring to FIG. 18, the inspection unit 540 may include a vision module 541, a measurement module 542, and a nozzle care module 543 and may stand by in the maintenance zone 420. The vision module 541 may be provided as an ejected ink inspection camera, and the measurement module 542 may be provided as an ejected ink inspection base. FIG. 18 illustrates the inspection unit 540 of the substrate treatment apparatus 100.

When maintenance is needed, the measurement module 542 and the nozzle care module 543 may move to where in the printing zone 410 the inkjet head unit 140 is located. In this case, the inkjet head unit 140 may be elevated, and the measurement module 542 and the nozzle care module 543 may move below the inkjet head unit 140. Then, various inspections and cleaning may be performed.

Thereafter, the measurement module 542 and the nozzle care module 543 may move to where in the maintenance zone 420 where the vision module 541 is located, and the control unit 160 may generate final inspection result data based on an image acquired by the vision module 541.

The substrate G may stand by or reside behind or outside the inkjet head unit 140 during maintenance.

The second stage 121 may be disposed on a higher level than the first stage 111, and not only the inspection unit 540, but also the second stage 121 where the inspection unit 540 is installed may move over to the first stage 111 to perform maintenance for the inkjet head unit 140.

For example, if the measurement module 542 moves to where in the printing zone 410 the inkjet head unit 140 is located to determine whether the substrate treatment liquid has been properly ejected from the nozzles 211, the inkjet head unit 140 may eject the substrate treatment liquid onto a film of the measurement module 542. Thereafter, the measurement module 542 may move to where in the maintenance zone 420 the vision module 541 is located. Then, the vision module 541 may inspect the state of the nozzles 211.

Alternatively, when the inkjet head unit 140 ejects the substrate treatment liquid onto the film of the measurement module 542, the vision module 541 may move to where in the printing zone 410 the measurement module 542 is located and may inspect the state of the nozzles 211.

Alternatively, the inkjet head unit 140 may move to where in the maintenance zone 420 the measurement module 542 is located, and may eject the substrate treatment liquid onto the film of the measurement module 542. Then, the vision module 541 may inspect the state of the nozzles 211.

The inspection unit 540 may inspect the ejection state of the nozzles 211 (e.g., the speed, volume, and target points of droplets) by performing various inspections for the inkjet head unit 140, may measure the amount of substrate treatment liquid ejected, the alignment of the nozzles 211, and may inspect the state of the nozzles 211 with the use of the ejected ink inspection camera and the ejected ink inspection base. Also, the inspection unit 540 may perform care and cleaning for nozzles 211 that have failed to eject the substrate treatment liquid or are defective by performing cleaning for the inkjet head unit 140, and may clean the surfaces of the nozzles 211.

The substrate treatment apparatus 100, which includes the inkjet head unit 140, the temperature control unit 510, the temperature measurement unit 530, and the inspection unit 540, has been described above with reference to FIGS. 1 through 18.

The substrate treatment apparatus 100 is characterized by being capable of performing high-resolution pixel printing on a large-size substrate. As already mentioned above, the substrate treatment apparatus 100 may include the processing unit 110, which includes the first stage 111, the maintenance unit 120, the gantry unit 130, and the inkjet head unit 140.

The inkjet head unit 140 may include the head packs 210, which include groups of multiple nozzles 211 for performing pixel printing on a large-size substrate, the head base 220, in which the head packs 210 are provided, and the head frame 230, which fixes the head base 220 and has the storage tank 151 and the pressure control module 152 mounted thereon.

The nozzles 211, which form the head packs 210, may overlap with one another to meet the resolution of an image to be printed on the substrate G. On the contrary, the head packs 210, which include groups of nozzles 211, may be arranged in a single row or column on the head base 220 not to overlap with one another.

The inkjet head unit 140 may include a measurement apparatus and a camera for identifying the flatness between, and the state of, the nozzles 211 or the head packs 210 in a base of the head frame 230. The inkjet head unit 140 may move slightly in an X-axis direction during the printing of the substrate G and may be elevated by as much as the height of maintenance equipment in a Z-axis direction.

The substrate treatment apparatus 100 may further include the inspection unit 540, which inspects and cleans the nozzles 211. The inspection unit 540 may include the vision module 541, the measurement module 542, and the nozzle care module 543 and may freely move between the printing zone 410 of the first stage 111 and the maintenance zone 420 of the second stage 121 for the inspection and cleaning of the nozzles 211.

The substrate treatment apparatus 100 may further include the temperature control unit 510, which is for controlling the viscosity of the substrate treatment liquid (e.g., ink). The temperature control unit 510 may control the temperature to minimize the influence of temperature variations on the nozzles 211 of the inkjet head unit 140. The temperature control unit 510 may be installed between the gantry unit 130 and the inkjet head unit 140.

The substrate treatment apparatus 100 may have the following advantages.

First, when the printing zone 410 and the maintenance zone 420 are separated, nozzle correction deviation may occur. However, as the printing zone 410 and the maintenance zone 420 are installed on the same line, ejection measurement error can be minimized.

Second, in order to print on a large-size substrate, the substrate needs to be divided into areas that can be covered with printing equipment. Specifically, printing may be performed on one area of the substrate and then on another area of the substrate, which, however, prolongs the entire printing duration and additionally consumes time to move from one area to another area of the substrate. However, according to embodiments of the present disclosure, the entire substrate can be covered during printing, and as a result, the overall process time (or tack time) can be reduced while preventing waste of time.

Third, when printing is performed on a large-size substrate by dividing the substrate into areas, the printing equipment needs to be moved between the areas of the substrate to perform printing. In this case, vibration occurs due to the movement of the head axis. However, according to embodiments of the present disclosure, the substrate does not need to be divided into areas to be printed on, and thus, vibration that may be caused by movements in an axial direction can be minimized. Also, various problems such as equipment misalignment or twist that may be caused by the load on the drive shaft because of a low-weight design can be addressed.

Embodiments of the present disclosure have been described above with reference to the accompanying drawings, but the present disclosure is not limited thereto and may be implemented in various different forms. It will be understood that the present disclosure can be implemented in other specific forms without changing the technical concept or gist of the present disclosure. Therefore, it should be understood that the embodiments set forth herein are illustrative in all respects and not limiting.

What is claimed is:

1. A substrate treatment apparatus comprising:
a processing unit supporting and moving a substrate;
an inkjet head unit performing pixel printing on the substrate; and
a gantry unit moving the inkjet head unit over the substrate,
wherein
the inkjet head unit includes head packs, which include a plurality of nozzles ejecting a substrate treatment liquid onto the substrate, and a head base, in which the head packs are installed, and
the head packs are disposed in a single row in the head base.

2. The substrate treatment apparatus of claim 1, wherein
the head packs include first and second head packs, which are adjacent to each other, and
the first and second packs are of different types.

3. The substrate treatment apparatus of claim 1, wherein
the head packs include first and second head packs, which are adjacent to each other, and
a nozzle of the first head pack that is adjacent to the second head pack does not overlap with a nozzle of the second head pack that is adjacent to the first head pack.

4. The substrate treatment apparatus of claim 1, wherein
the head packs include first and second head packs, which are adjacent to each other, and
the first and second head packs are spaced apart from each other.

5. The substrate treatment apparatus of claim 4, wherein
a distance between the first and second head packs is the same as a size of the head packs.

6. The substrate treatment apparatus of claim 1, wherein
a size of the head packs combined is the same as a size of the substrate.

7. The substrate treatment apparatus of claim 1, wherein a plurality of nozzles included in one head pack overlap with one another depending on a resolution of an image to be formed on the substrate.

8. The substrate treatment apparatus of claim 1, wherein
the inkjet head unit further includes a head frame, which is installed on the head base, and
the head frame includes a storage tank, which stores the substrate treatment liquid, and a pressure control module, which controls a meniscus associated with the substrate treatment liquid.

9. The substrate treatment apparatus of claim 1, further comprising:
a maintenance unit for the maintenance of the inkjet head unit,
a first stage of the processing unit and a second stage of the maintenance unit are disposed side-by-side in a moving direction of the gantry unit.

10. The substrate treatment apparatus of claim 1, wherein the gantry unit is a single gantry unit supporting the inkjet head unit, on one side of the inkjet head unit.

11. The substrate treatment apparatus of claim 1, further comprising:
a temperature control unit controlling the temperature of the substrate treatment liquid.

12. The substrate treatment apparatus of claim 11, wherein the temperature control unit is provided in the inkjet head unit or between the gantry unit and the inkjet head unit.

13. The substrate treatment apparatus of claim 1, further comprising:
a temperature control unit controlling the temperature of the substrate,
wherein the temperature control unit is provided on a first stage of the processing unit.

14. The substrate treatment apparatus of claim 1, further comprising:
a plurality of temperature measurement units installed on a surface of the inkjet head unit.

15. The substrate treatment apparatus of claim 14, further comprising:
a temperature control unit controlling the temperature of the substrate treatment liquid using a difference between a temperature measurement from a temperature measurement unit installed on a first surface of the inkjet head unit and a temperature measurement from a temperature measurement unit installed on a second surface of the inkjet head unit.

16. The substrate treatment apparatus of claim 1, further comprising:
a maintenance unit for the maintenance of the inkjet head unit; and
an inspection unit provided on a second stage of the maintenance unit.

17. The substrate treatment apparatus of claim 16, wherein the inspection unit includes a measurement module, which measures droplets ejected from nozzles of the inkjet head unit, a vision module, which inspects the droplets, and a nozzle care module, which cleans the nozzles.

18. The substrate treatment apparatus of claim 16, wherein the second stage is formed on a different level from a first stage of the processing unit.

19. A substrate treatment apparatus comprising:
a processing unit supporting and moving a substrate;
an inkjet head unit performing pixel printing on the substrate;
a gantry unit moving the inkjet head unit over the substrate; and
a maintenance unit for the maintenance of the inkjet head unit,
wherein
the inkjet head unit includes head packs, which include a plurality of nozzles ejecting a substrate treatment liquid onto the substrate, a head base, in which the head packs are installed, and a head frame, which is installed on the head base and includes a storage tank storing the substrate treatment liquid and a pressure control module controlling a meniscus associated with the substrate treatment liquid, at the nozzles,
the head packs are disposed in a single row in the head base,
the head packs include first and second head packs, which are adjacent to each other and are of different types,
a nozzle of the first head pack that is adjacent to the second head pack does not overlap with a nozzle of the second head pack that is adjacent to the first head pack,
a size of the head packs combined is the same as a size of the substrate, and
a first stage of the processing unit and a second stage of the maintenance unit are disposed side-by-side in a moving direction of the gantry unit.

20. An inkjet head unit performing pixel printing on a substrate, comprising:
head packs including a plurality of nozzles, which eject a substrate treatment liquid onto the substrate;
a head base in which the head packs are installed; and
a head frame installed on the head base, the head frame including a storage tank, which stores the substrate treatment liquid, and a pressure control module, which controls a meniscus associated with the substrate treatment liquid, at the nozzles,
wherein the head packs are disposed in a single row in the head base.
